(19) United States
(12) Patent Application Publication
(10) Pub. No.: US 2025/0239515 A1
(43) Pub. Date: Jul. 24, 2025

(54) SEMICONDUCTOR PACKAGE

(71) Applicant: Samsung Electronics Co., Ltd., Suwon-si (KR)

(72) Inventor: Dohyuk YOO, Suwon-si (KR)

(21) Appl. No.: 18/777,595

(22) Filed: Jul. 19, 2024

(30) Foreign Application Priority Data
Jan. 22, 2024 (KR) 10-2024-0009602

(51) Int. Cl. H01L 23/498; H01L 21/48; H01L 23/00

(52) U.S. Cl. CPC H01L 23/49838; H01L 21/4857; H01L 21/486; H01L 23/49822; H01L 23/49894; H01L 24/16; H01L 24/32; H01L 24/73; H01L 2224/16227; H01L 2224/16237; H01L 2224/32225; H01L 2224/73204; H01L 2924/301

(57) ABSTRACT

A semiconductor package includes a substrate. The substrate includes a first insulating pattern, first conductive patterns extending horizontally on an upper surface of the first insulating pattern, a second insulating pattern covering the first conductive pattern on the upper surface of the first insulating pattern, substrate pads disposed on the second insulating pattern and being part of respective second conductive patterns that vertically penetrate the second insulating pattern and are connected to the first conductive patterns, and an insulating layer covering the substrate pads on the second insulating pattern and exposing a portion of each substrate pad of the substrate pads. The second insulating pattern may have penetration holes vertically penetrating the second insulating pattern. Each of the penetration holes may be disposed between two adjacent pads of the substrate pads. The insulating layer may fill the penetration holes.

### CROSS-REFERENCE TO RELATED APPLICATIONS

This U.S. non-provisional patent application claims priority under 35 U.S.C. § 119 to Korean Patent Application No. 10-2024-0009602 filed on Jan. 22, 2024, in the Korean Intellectual Property Office, the entire contents of which are hereby incorporated by reference.

### BACKGROUND OF THE INVENTION

The inventive concept relates to a semiconductor package and a method of manufacturing the same.

With the development of the electronics industry, there is a growing demand for high-performance, high-speed and miniaturization of electronic components. Accordingly, a substrate on which the semiconductor chip is mounted is also required to have fine circuitry, excellent electrical characteristics, high reliability, high-speed signal transmission structure, and high functionality.

A surface of the semiconductor package substrate may include solder resist. Typically, when connecting electrodes and lead wirings on an interconnection substrate with solders, it is common to deposit a solder resist on the surface of the interconnection substrate. To realize the excellent electrical characteristics of semiconductor packages, technology to stably deposit the solder resist on the interconnection substrate and to maintain the solder resist under various environmental conditions is desirable.

### SUMMARY

Aspects of the inventive concept provide to a semiconductor package with improved structural stability and a method of manufacturing the same.

Problems to be solved by the invention are not limited to the problems mentioned above, and other problems not mentioned will be clearly understood by those skilled in the art from the description below.

A semiconductor package according to some embodiments includes a substrate. The substrate includes a first insulating pattern, first conductive patterns extending horizontally on an upper surface of the first insulating pattern, a second insulating pattern covering the first conductive pattern on the upper surface of the first insulating pattern, substrate pads disposed on the second insulating pattern and being part of respective second conductive patterns that vertically penetrate the second insulating pattern and are connected to the first conductive patterns, and an insulating layer covering the substrate pads on the second insulating pattern and exposing a portion of each substrate pad of the substrate pads. The second insulating pattern may have penetration holes vertically penetrating the second insulating pattern. Each of the penetration holes may be disposed between two adjacent pads of the substrate pads. The insulating layer may fill the penetration holes.

A semiconductor package according to some embodiments of the inventive concept may include a substrate. The substrate may include a protective pattern, a first conductive pattern horizontally spaced apart from the protective pattern, a first insulating pattern covering the protective pattern and the first conductive pattern, a penetration hole vertically penetrating the first insulating pattern, a substrate pad disposed at an upper surface of the first conductive pattern, and an insulating layer covering an upper surface of the first insulating pattern and surrounding a side surface of the substrate pad. The penetration hole may be disposed on an upper surface of the protective pattern. The upper surface of the protective pattern may be exposed by the penetration hole. The insulating layer may fill the penetration hole and cover the exposed upper surface of the protective pattern.

A semiconductor package according to some embodiments of the inventive concept may include a substrate, a semiconductor chip disposed on an upper surface of the substrate, a molding layer surrounding the semiconductor chip on the upper surface of the substrate, an external terminal disposed on a lower surface of the substrate, a connection terminal provided on a lower surface of the semiconductor chip. The substrate may include an internal insulating pattern, a first conductive pattern extending horizontally on a upper surface of the internal insulating pattern, an external insulating pattern covering the first conductive pattern on the upper surface of the internal insulating pattern, a second conductive pattern disposed on an upper surface of the external insulating pattern and vertically penetrating the external insulating pattern and connected to the first conductive pattern, a substrate pad disposed on the upper surface of the external insulating pattern and being part of the second conductive pattern, and a protective layer covering the upper surface of the external insulating pattern and having an opening exposing the substrate pad. The connection terminal may be connected to the substrate pad through the opening in the protective layer. The protective layer may include a protrusion protruding from a lower surface of the protective layer. The protrusion may have a first depth and extend from the lower surface of the protective layer in a direction perpendicular to the upper surface of the external insulating pattern. The protective layer may surround at least a portion of a side surface of the connection terminal.

### BRIEF DESCRIPTION OF THE DRAWINGS

Example embodiments will be more clearly understood from the following brief description taken in conjunction with the accompanying drawings. The accompanying drawings represent non-limiting, example embodiments as described herein.

FIG. 1 is a cross-sectional view illustrating a semiconductor package according to embodiments of the inventive concept.

FIG. 2 is an enlarged view for illustrating a substrate according to an embodiment of the inventive concept, and corresponds to region ‘A’ in FIG. 1.

FIGS. 3 and 4 are plan views for illustrating a semiconductor package according to embodiments of the inventive concept.

FIGS. 5 and 6 are cross-sectional views illustrating semiconductor packages according to embodiments of the inventive concept.

FIGS. 7 to 11 are cross-sectional views for illustrating a method of manufacturing a semiconductor package according to embodiments of the inventive concept.

### DETAILED DESCRIPTION

Hereinafter, a semiconductor package according to aspects of the inventive concept will be described with reference to the drawings.

Terms It will be understood that, although the terms first, second, third etc. may be used herein to describe various elements, components, regions, layers and/or sections, these elements, components, regions, layers and/or sections should not be limited by these terms. Unless the context indicates otherwise, these terms are only used to distinguish one element, component, region, layer or section from another element, component, region, layer or section, for example as a naming convention. Thus, a first element, component, region, layer or section discussed below in one section of the specification could be termed a second element, component, region, layer or section in another section of the specification or in the claims without departing from the teachings of the present invention. In addition, in certain cases, even if a term is not described using “first,” “second,” etc., in the specification, it may still be referred to as “first” or “second” in a claim in order to distinguish different claimed elements from each other.

such as “same,” “equal,” “planar,” or “coplanar,” as used herein when referring to orientation, layout, location, shapes, sizes, compositions, amounts, or other measures do not necessarily mean an exactly identical orientation, layout, location, shape, size, composition, amount, or other measure, but are intended to encompass nearly identical orientation, layout, location, shapes, sizes, compositions, amounts, or other measures within acceptable variations that may occur resulting from conventional manufacturing processes. The term “substantially” may be used herein to emphasize this meaning, unless the context or other statements indicate otherwise. For example, items described as “substantially the same,” “substantially equal,” or “substantially planar,” may be exactly the same, equal, or planar, or may be the same, equal, or planar within acceptable variations that may occur, for example, due to manufacturing processes.

It will be understood that when an element is referred to as being “connected” or “coupled” to or “on” another element, it can be directly connected or coupled to or on the other element or intervening elements may be present. In contrast, when an element is referred to as being “directly connected” or “directly coupled” to another element, or as “contacting” or “in contact with” another element (or using any form of the word “contact”), there are no intervening elements present at the point of contact.

Throughout the specification, when a component is described as “including” a particular element or group of elements, it is to be understood that the component is formed of only the element or the group of elements, or the element or group of elements may be combined with additional elements to form the component, unless the context indicates otherwise. The term “consisting of,” on the other hand, indicates that a component is formed only of the element(s) listed.

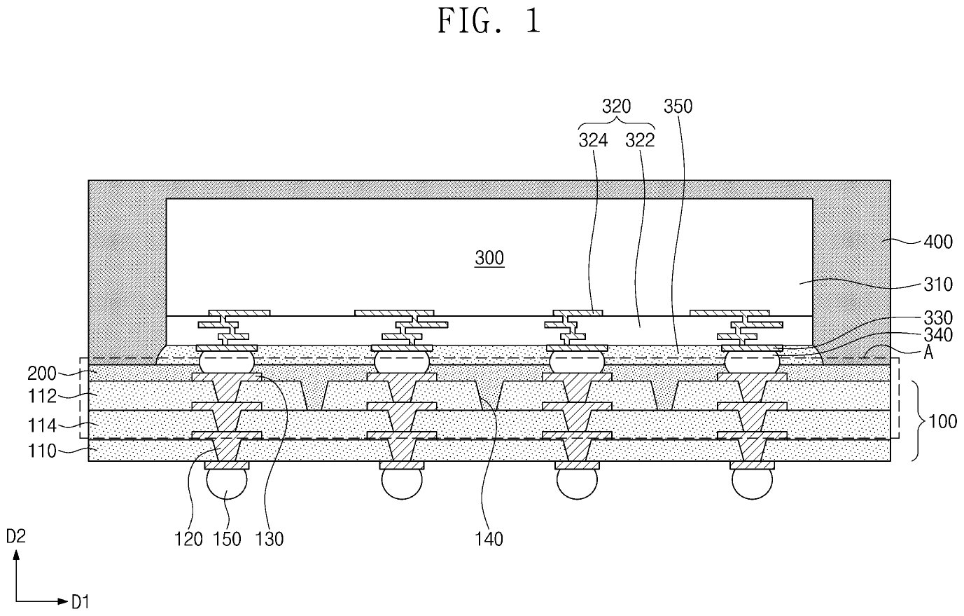

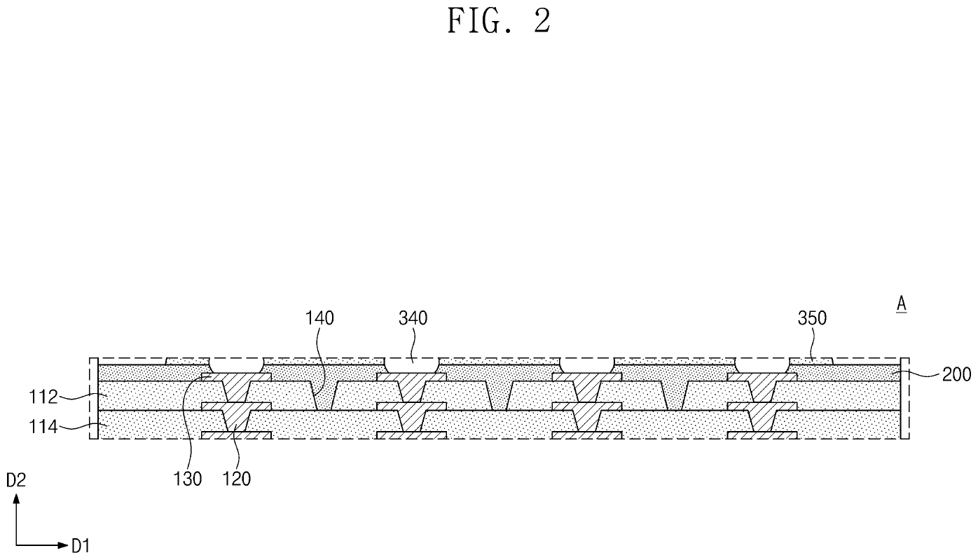

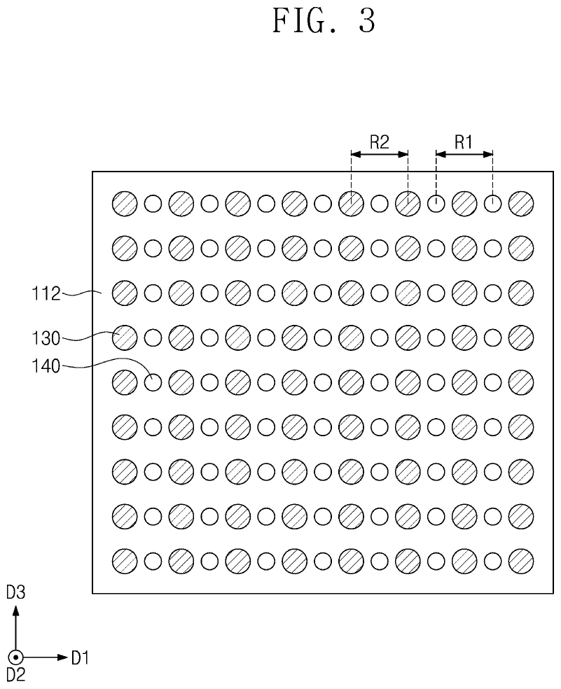

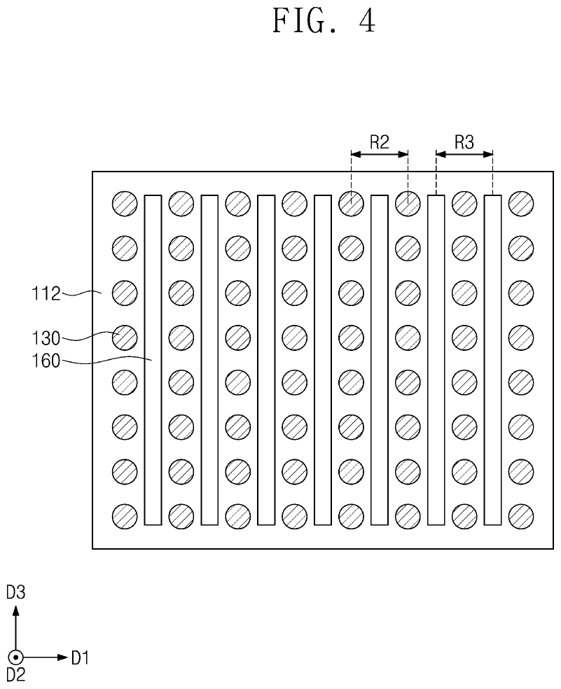

FIG. 1 is a cross-sectional view illustrating a semiconductor package according to embodiments of the inventive concept. FIG. 1 shows that the number of substrate pads and penetration holes of the semiconductor package is small for convenience of explanation. FIG. 2 is an enlarged view for illustrating a substrate according to an embodiment of the inventive concept, and corresponds to region ‘A’ in FIG. 1. FIGS. 3 and 4 are plan views for illustrating a semiconductor package according to embodiments of the inventive concept.

Referring to FIG. 1, a substrate 100 is provided. The substrate 100 may be a redistribution substrate. The substrate 100 may include one substrate wiring layer or at least two substrate wiring layers stacked on each other. In this specification, a substrate wiring layer may refer to a wiring layer formed by patterning one insulating material layer and one conductive material layer, respectively. For example, the conductive patterns in one substrate wiring layer may be lines that extend horizontally at a particular vertical level, and do not overlap each other vertically. Each of the substrate wiring layers may include a first insulating pattern 110 and a first conductive pattern 120 in the first insulating pattern 110. The first conductive pattern 120 of one substrate wiring layer may be electrically connected to the first conductive pattern 120 of another adjacent substrate wiring layer. Hereinafter, the first insulating pattern 110 and the first conductive pattern 120 will be described based on one of the substrate wiring layers. It should be noted that although one first conductive pattern 120 may be described below, as can be seen in FIG. 1, a plurality of first conductive patterns may be formed. The description of a conductive pattern may refer to an individual instance a conductive component, or the group of components that form a pattern in a particular process at a particular level within the substrate 100. Each component (e.g., the single component labeled 120 in FIG. 1) may be alternatively described as a conductive rivet, conductive rivet-shaped plug, or a conductive plug, for example having a planar top portion and a through-via extending therefrom, so that for each substrate wiring layer, a plurality of conductive rivets or conductive plugs may be formed.

The first insulating pattern 110 may include an inorganic insulating layer such as silicon oxide (SiOx) or silicon nitride (SiNx). Alternatively, the first insulating pattern 110 may include a polymer material. The first insulating pattern 110 may include an insulating polymer or a photoimageable dielectric (PID). For example, the photoimageable dielectric may include at least one of photosensitive polyimide, polybenzoxazole (PBO), phenol-based polymer, or benzocyclobutene-based polymer.

The first conductive pattern 120 may be provided on an upper surface of the first insulating pattern 110. The first conductive pattern 120 may protrude onto the upper surface of the first insulating pattern 110 (e.g., may protrude horizontally from a central portion). The first conductive pattern 120 may extend horizontally on the upper surface of the first insulating pattern 110. The first conductive pattern 120 may be covered by another first insulating pattern 110 disposed on the upper surface of the first insulating pattern 110. As described above, the first conductive pattern 120 may be a pad portion or a wiring portion of the substrate wiring layer. The first conductive pattern 120 may be configured for horizontal redistribution in the substrate 100. The first conductive pattern 120 may include a conductive material. For example, the first conductive pattern 120 may include copper (Cu).

The first conductive pattern 120 may have a damascene structure. For example, the first conductive pattern 120 may have a via protruding from a lower surface thereof. The via may be configured to connect first conductive patterns 120 that are vertically adjacent to each other. For example, the via may extend from a lower surface of the first conductive pattern 120, penetrate the first insulating pattern 110, and be connected to the upper surface of the first conductive pattern 120 of another substrate wiring layer located therebelow. For example, an upper portion of the first conductive pattern 120 on the first insulating pattern 110 may be a head portion used as a horizontal wiring or pad, and the via of the first conductive pattern 120 may be a tail portion. The first conductive pattern 120 may have a T-shape. The first conductive pattern 120 may also be described as having a vertical portion (e.g., the via) and a horizontal portion (e.g., the top plate forming the top of the T-shape).

Although FIG. 1 shows that the via of the first conductive pattern 120 is connected to the lower surface of the first conductive pattern 120, the inventive concept is not limited thereto. According to other embodiments, the tail portion of the first conductive pattern 120 may have an inverted ‘T-shaped’ form that protrudes above the head portion.

As an example of the inverted T-shape, the first conductive pattern 120 may be provided on a lower surface of the first insulating pattern 110. The first conductive pattern 120 may protrude horizontally from a central portion onto the lower surface of the first insulating pattern 110. The first conductive pattern 120 may extend horizontally on the lower surface of the first insulating pattern 110. The first conductive pattern 120 may be covered by another first insulating pattern 110 disposed below the lower surface of the first insulating pattern 110. The first conductive pattern 120 may have a via protruding above an upper surface thereof. The via may be configured to vertically connect adjacent first conductive patterns 120 to each other. For example, the via may extend from the upper surface of the first conductive pattern 120, penetrate the first insulating pattern 110, and be connected to the lower surface of another first conductive pattern 120 disposed thereon. Accordingly, an upper portion of the first conductive pattern 120 on the lower surface of the first insulating pattern 110 may be a head portion used as a horizontal wiring or pad, and the via of the first conductive pattern 120 may a tail portion. Hereinafter, the description will continue based on the embodiment of FIG. 1.

The substrate 100 may include substrate pads 130 provided on an upper surface of the substrate 100. The substrate pads 130 may be arranged to be spaced apart from each other on the upper surface of the substrate 100. The substrate pads 130 may protrude horizontally from a central portion onto the upper surface of the substrate 100. In this case, the substrate pads 130 may be portion of the first conductive pattern 120 that protrudes from the first insulating pattern 110 of the substrate wiring layer disposed at the uppermost layer thereof. Alternatively, the substrate pads 130 may be separate pads that vertically penetrate the first insulating pattern 110 of the substrate wiring layer disposed at the uppermost layer thereof and are connected to the first conductive pattern 120. The substrate pads 130 may be electrically connected to the substrate 100 through the first conductive pattern 120 in the first insulating pattern 110 of the substrate wiring layer disposed at the uppermost layer thereof.

The substrate pads 130 may be arranged in at least one row on the upper surface of the substrate 100 when viewed in a plan view. The substrate pads 130 may have a plurality of rows extending in a third direction D3. The substrate pads 130 may be spaced apart from each other in the third direction D3 in each row. The plurality of rows may be arranged to be spaced apart from each other in a first direction D1. In this specification, the first direction D1 may be defined as a direction parallel to the upper surface of the substrate 100, and a second direction D2 may be defined as a direction perpendicular to the upper surface of the substrate 100. In this specification, the third direction D3 may be a direction that intersects the first direction D1 and the second direction D2. However, as mentioned above, the labels “first,” “second,” and “third” may be used as naming conventions to refer to any particularly defined direction.

FIG. 1 shows that the substrate 100 is a redistribution substrate, but the inventive concept is not limited thereto. The substrate 100 may alternatively be a printed circuit board (PCB) or a semiconductor substrate. In these cases, the substrate 100 may have upper substrate pads and an internal wiring pattern. The upper substrate pads may be provided on the upper surface of the substrate 100, and a semiconductor chip 300, which will be described later, may be mounted thereon. The internal wiring pattern may be provided in the substrate 100 and may be electrically connected to the upper substrate pads. Hereinafter, the description will continue based on the embodiment of FIG. 1.

The first insulating pattern 110 of the substrate wiring layer disposed at the uppermost layer thereof may be described as an external insulating pattern 112, or external insulating layer, and the first insulating pattern 110 of the substrate wiring layer disposed below the external insulating pattern 112 among the substrate wiring layers may be described as an internal insulating pattern 114, or internal insulating layer. A lower surface of the external insulating pattern 112 and an upper surface of the internal insulating pattern 114 may be in contact with each other. The lower surface of the external insulating pattern 112 and the upper surface of the internal insulating pattern 114 may be coplanar. A height (e.g., thickness in the vertical, or D2, direction) of the external insulating pattern 112 may be about 10 μm to about 35 μm.

The substrate 100 may have penetration holes 140 at the upper surface of the substrate 100. As viewed from a plan view, each of the penetration holes 140 may be disposed between any two of adjacent substrate pads 130 on the upper surface of the external insulating pattern 112. The penetration holes 140 may be arranged in at least one row on the upper surface of the substrate 100 when viewed in a plan view. The penetration holes 140 may have a plurality of rows extending in the third direction D3. The penetration holes 140 may be spaced apart from each other in the third direction D3 in each row. The plurality of rows may be arranged to be spaced apart from each other in the first direction D1. Each of the plurality of rows may be disposed between two adjacent rows of the rows of the substrate pads 130. The plurality of rows may be arranged alternately with the rows of the substrate pads 130 in the first direction D1. A distance between the penetration holes 140 in each row may be the same as a distance between the substrate pads 130 in each row. However, the inventive concept is not limited thereto.

When viewed in a plan view, the penetration holes 140 may have a circular shape. However, the inventive concept is not limited thereto. According to other embodiments, a planar shape of the penetration holes 140 may be polygonal. A depth of the penetration holes 140 in the second direction D2 may be about 10 μm to about 35 μm. The depth of the penetration holes 140 in the second direction D2 may be equal to a height of the external insulating pattern 112. The height of the penetration holes 140 in the second direction D2 (e.g., from a top to a bottom of each hole) may be greater than a height of a via of the first conductive pattern 120 formed in part at the same vertical level as the penetration holes 140. In one embodiment, the penetration holes 140 completely penetrate the external insulating pattern 112 vertically, and the upper surface of the internal insulating pattern 114 may be exposed through the penetration holes 140. The lowermost end of the penetration holes 140 may terminate at the upper surface of the internal insulating pattern 114. A cross-sectional shape of each penetration hole 140 may have a tapered shape. A width of the penetration holes 140 may increase as a distance from the internal insulating pattern 114 increases. A width of the penetration holes 140 measured on the lower surface of the external insulating pattern 112 may be about 0.6 to about 0.9 times a width of the penetration holes 140 measured on the upper surface of the external insulating pattern 112. In this case, the width of the penetration holes 140 measured at the upper surface of the external insulating pattern 112 (e.g., a maximum width of the penetration holes 140) may be about 40 μm to about 100 μm. FIG. 1 shows that the width of the penetration holes 140 increases as the distance from the internal insulating pattern 114 increases, but the inventive concept is not limited thereto. The width of the penetration holes 140 may be constant along the second direction D2. A distance between two adjacent penetration holes 140 may be about 0.8 to about 1.2 times a distance between two adjacent substrate pads 130 of the substrate pads 130.

FIG. 1 shows the penetration holes 140 completely penetrate the external insulating pattern 112 to expose the upper surface of the internal insulating pattern 114, but the inventive concept is not limited thereto. The penetration holes 140 may not completely penetrate the external insulating pattern 112. The penetration holes 140 may have a recessed shape from the upper surface of the external insulating pattern 112 toward the lower surface of the external insulating pattern 112. The bottom surface of the penetration holes 140 may be positioned at a higher level than the upper surface of the internal insulating pattern 114. A level of the bottom surface of the penetration holes 140 may be higher than a level of a lower surface of the external insulating pattern 112. In a region where the penetration holes 140 are provided, the upper surface of the internal insulating pattern 114 may not be exposed to the outside surface. For example, the entire upper surface of the internal insulating pattern 114 may be covered by the external insulating pattern 112. A depth of the penetration holes 140 in the second direction D2 may be equal to or smaller than a height (e.g., vertical thickness) of the external insulating pattern 112 and may be greater than ⅓ of the height of the external insulating pattern 112 (e.g., the depth of the penetration holes 140 in the second direction D2 may be between ⅓ and 1 times the depth of the external insulating pattern 112).

Alternatively, the penetration holes 140 may penetrate the external insulating pattern 112 and at least a portion of the internal insulating pattern 114 in a vertical direction. The penetration holes 140 may have a recessed shape from the upper surface of the external insulating pattern 112 toward the lower surface of the internal insulating pattern 114. a depth of the penetration holes 140 in the second direction D2 may be greater than a height of the external insulating pattern 112. The bottom of the penetration holes 140 may terminate at a level lower than a level of the uppermost surface of the internal insulating pattern 114.

External terminals 150 may be provided on the lower surface of the substrate 100. The external terminals 150 may be disposed on substrate lower pads provided on the lower surface of the substrate 100. In this case, the substrate lower pads may be portion of the first conductive pattern 120 exposed on the lower surface of the substrate 100, or may be separate pads disposed on the first insulating pattern 110 of the substrate 100 and connected to the first conductive pattern. 120. The external terminals 150 may include, for example, solder balls or solder bumps.

A protective layer 200 may be formed on the upper surface of the substrate 100. The protective layer 200 may entirely cover the upper surface of the external insulating pattern 112. The protective layer 200 may cover the substrate pads 130 on the upper surface of the substrate 100 and may have an opening exposing a portion of each pad of the substrate pads 130. The protective layer 200 may cover at least portion of each pad of the substrate pads 130 and expose the remaining portion. For example, the protective layer 200 may surround side surfaces of each pad of the substrate pads 130 and cover at least a portion of the upper surface of each pad of the substrate pads 130. The protective layer 200 may contact both the side surfaces of the substrate pads 130 and the upper surface of the substrate pads 130. The protective layer 200 may cover an outer portion of the upper surface of the substrate pads 130. A central portion of the upper surface of the substrate pads 130 may be exposed with respect to an upper surface of the protective layer 200. The protective layer 200 may fill the penetration holes 140 disposed on the upper surface of the external insulating pattern 112. As the protective layer 200 fills the penetration holes 140 and covers the upper surface of the substrate 100, the protective layer 200 may have protrusions that protrude below and from the lower surface of the protective layer 200. Therefore, the protrusions may have a first depth and may extend from the lower surface of the protective layer 200 in a direction perpendicular to the upper surface of the external insulating pattern 112. The protective layer 200 may include, for example, a gel-soft polymer, such as a solder resist material. The protective layer 200 may include an insulating material. For example, the insulating material may include one of epoxy resin, polyimide resin, BT resin, and Teflon resin.

A semiconductor chip 300 may be provided on the upper surface of the substrate 100. A lower surface of the semiconductor chip 300 may be an active surface. The semiconductor chip 300 may include a chip base layer 310 and a chip wiring layer 320.

The chip base layer 310 may include a semiconductor substrate. For example, the chip base layer 310 may be a semiconductor substrate such as a semiconductor wafer. The chip base layer 310 may be a silicon (Si) substrate, a silicon-on-insulator (SOI) substrate, a germanium (Ge) substrate, a germanium-on-insulator (GOI) substrate, a silicon-germanium (SiGe) substrate, a group 3-5 semiconductor substrate, or a substrate of an epitaxial thin layer obtained by performing selective epitaxial growth (SEG). The chip base layer 310 may include at least one of, for example, silicon (Si), germanium (Ge), silicon-germanium (SiGe), gallium arsenide (GaAs), indium gallium arsenide (InGaAs), aluminum gallium arsenide (AlGaAs), or mixtures thereof. Although not shown, an integrated circuit may be provided on the lower surface of the chip base layer 310. The integrated circuit may include a logic circuit or a memory circuit. For example, the semiconductor chip 300 may be a logic chip or a memory chip. However, the inventive concept is not limited thereto, and the semiconductor chip 300 may include a logic chip, a memory chip, a semiconductor chip including various direct devices, or a passive device.

The chip wiring layer 320 may be disposed on the lower surface of the chip base layer 310. For example, the chip wiring layer 320 may include a chip insulating pattern 322 and a chip wiring pattern 324 formed on the lower surface of the chip base layer 310. The chip wiring layer 320 may further include a circuit pattern or a protective layer, as needed.

The chip insulating pattern 322 may cover the integrated circuit on the lower surface of the chip base layer 310. The chip insulating pattern 322 may include an insulating material. For example, the chip insulating pattern 322 may include silicon oxide (SiO), silicon nitride (SiN), silicon oxynitride (SiON), silicon carbonitride (SiCN), or an insulating polymer. Alternatively, the chip insulating pattern 322 may include an insulating polymer or a photoimageable dielectric (PID). For example, the photoimageable dielectric may include at least one of photosensitive polyimide, polybenzoxazole, phenol-based polymer, or benzocyclobutene-based polymer.

The chip wiring pattern 324 may be provided in the chip insulating pattern 322. The chip wiring pattern 324 may be electrically connected to the integrated circuit formed on the lower surface of the chip base layer 310. The chip wiring pattern 324 may include a conductive material. For example, the chip wiring pattern 324 may include copper (Cu) or aluminum (Al).

The semiconductor chip 300 may include lower pads 330 provided on the lower surface of the semiconductor chip 300. The lower pads 330 may be disposed on the lower surface of the semiconductor chip 300, for example, a lower surface of the chip wiring layer 320. For example, the lower pads 330 may protrude from the lower surface of the semiconductor chip 300. In this case, the lower pads 330 may be a portion of the chip wiring pattern 324 that protrudes from the chip insulating pattern 322 of the chip wiring layer 320, or may be separate pads disposed on the chip insulating pattern 322 of the chip wiring layer 320 and connected to the chip wiring pattern 324. The lower pads 330 may be electrically connected to the integrated circuit formed on the lower surface of the chip base layer 310 through the chip wiring pattern 324 in the chip wiring layer 320.

Connection terminals 340, such as solder balls or solder bumps, may be provided on the lower pads 330 of the semiconductor chip 300. The semiconductor chip 300 may be mounted on the substrate 100 using connection terminals 340. For example, the connection terminals 340 may be provided between the substrate pads 130 of the substrate 100 and the lower pads 330 of the semiconductor chip 300. An upper surface of each of the connection terminals 340 may be in contact with the lower surface of the corresponding lower pads 330. A lower surface of each of the connection terminals 340 may be in contact with a center of the upper surface of the corresponding substrate pads 130. The protective layer 200 may surround an outer portion of the upper surface of the substrate pads 130 and at least a portion of side surfaces of the connection terminals 340. The upper portions of the side surfaces of the connection terminals 340 may be exposed with respect to the substrate 100 on the upper surface of the substrate 100. The connection terminals 340 may electrically connect the substrate pads 130 and the lower pads 330. As depicted in FIGS. 1 and 2, the semiconductor chip 300 may be mounted on the substrate 100 in a flip chip bonding manner.

An underfill layer 350 may be provided between the upper surface of the substrate 100 and the semiconductor chip 300. The underfill layer 350 may fill the spaces between the substrate 100 and the semiconductor chip 300 and surround the connection terminals 340. The underfill layer 350 may be provided only in the space between the substrate 100 and the semiconductor chip 300. The underfill layer 350 may not be provided on an region of the substrate 100 where the semiconductor chip 300 is not provided, and the upper surface of the substrate 100 may be exposed with respect to the underfill layer 350 at those locations. Alternatively, the underfill layer 350 may cover the entire upper surface of the substrate 100. According to other embodiments, the underfill layer 350 may not be provided as needed.

A molding layer 400 may be provided on the semiconductor chip 300. The molding layer 400 may cover the upper surface of the substrate 100 and the semiconductor chip 300. The molding layer 400 may include an insulating material. For example, the molding layer 400 may include epoxy molding compound (EMC).

FIG. 3 is a plan view for illustrating an arrangement of substrate pads and penetration holes according to embodiments of the inventive concept.

Referring to FIG. 3, as described with reference to FIG. 1, the substrate pads 130 may be arranged in at least one row on the upper surface of the substrate 100 when viewed in a plan view. The substrate pads 130 may have a plurality of rows extending in the third direction D3. The substrate pads 130 may be spaced apart from each other in the third direction D3 in each row. The plurality of rows may be arranged to be spaced apart from each other in the first direction D1.

The penetration holes 140 may be arranged in at least one row on the upper surface of the substrate 100 when viewed in a plan view. The penetration holes 140 may form a row extending in the third direction D3 between two adjacent rows of the substrate pads 130. The row of penetration holes 140 may be one of a plurality of rows of penetration holes 140. The penetration holes 140 may be aligned and spaced apart from each other in the third direction D3 in each row. The plurality of rows of penetration holes 140 may be arranged to be spaced apart from each other in the first direction D1. Each of the plurality of rows of penetration holes 140 may be disposed between two adjacent rows of substrate pads 130. On the substrate 100, rows of penetration holes 140 and rows of substrate pads 130 may be alternately arranged. The penetration holes 140 may be arranged to be spaced apart from the substrate pads 130 in the first direction D1. For example, when the substrate pads 130 are arranged in two rows in the third direction D3, the penetration holes 140 may be arranged in one row between the first and second row of substrate pads. In this specification, a first row of substrate pads may refer to the substrate pads 130 arranged in one of the two rows. In this specification, a second row of substrate pads may refer to the substrate pads 130 arranged in the remaining one of the two rows. The first row and second row substrate pads may be disposed on opposite side surfaces of each of the penetration holes 140 in the first direction D1. A first distance R1 between any two penetration holes 140 adjacent in the first direction D1 among the penetration holes 140 may be about 0.8 to about 1.2 times a second distance R2 between any two adjacent substrate pads 130 in the first direction D1 among the substrate pads 130. In addition, a minimum distance between any two adjacent substrate pads 130 in the first direction may be smaller than (e.g., may be about 0.5 to about 0.8 times) a minimum distance between any two adjacent penetration holes 140 in the first direction.

FIG. 3 shows that the number of substrate pads 130 arranged in one row is the same as the number of penetration holes 140 arranged in a row adjacent to the row and the distance at which the penetration holes 140 are spaced apart from each row is the same as the distance at which the substrate pads 130 are spaced within each row, but the inventive concept is not limited thereto. The number of penetration holes 140 disposed in a row adjacent to the row may be less than the number of substrate pads 130 disposed in one row. The distance at which the penetration holes 140 are spaced apart in each row may be greater than the distance at which the substrate pads 130 are spaced in each row. The number of penetration holes 140 arranged in one row may be changed as needed.

FIG. 4 is a plan view for illustrating an arrangement of substrate pads and penetration holes according to embodiments of the inventive concept. FIG. 4 is shown with some components omitted for convenience of explanation. Similar to FIG. 3, the substrate pads 130 may be arranged in at least one row on the upper surface of the substrate 100 when viewed in a plan view. The substrate pads 130 may have a plurality of rows extending in the third direction D3. The substrate pads 130 may be spaced apart from each other in the third direction D3 in each row. The plurality of rows may be arranged to be spaced apart from each other in the first direction D1.

Recesses 160 may be provided between two adjacent rows of the plurality of rows of substrate pads 130, respectively. The recesses 160 may be disposed on the upper surface of the external insulating pattern 112. Each of the recesses 160 may have a shape in which the penetration holes 140 arranged in one row extending in the third direction D3 among the penetration holes 140 (see FIG. 3) described with reference to FIG. 3 are connected without an interface. Therefore, each recess 160 may have a line shape. A plurality of recesses 160 may be provided on the upper surface of the substrate 100 when viewed in a plan view. The plurality of recesses 160 may be arranged to be spaced apart from each other in the first direction D1. Rows of the recesses 160 and substrate pads 130 may be alternately arranged on the substrate 100. At least one substrate pad 130 may be disposed on opposite side surfaces of each of the recesses 160 in the first direction D1. The recesses 160 may be arranged to be spaced apart from the substrate pads 130 in the first direction D1. The recesses 160 may extend in the third direction D3. A length of the recesses 160 in the third direction D3 may be greater than a distance between any two of the adjacent substrate pads 130 in the third direction D3. A planar shape of the recesses 160 (from a plan view) may be oval or polygonal. A depth of the recesses 160 in the second direction D2 may be about 10 μm to about 35 μm. The depth of the recesses 160 in the second direction D2 may be equal to a height of the external insulating pattern 112. However, the inventive concept is not limited thereto. A height of the recesses 160 in the second direction D2 may be greater than ⅓ of a height of the external insulating pattern 112. A width of the recesses 160 in the first direction D1 may become smaller as a distance from the external insulating pattern 112 increases. A cross-sectional shape of the recesses 160 may have a tapered shape. A width of the recesses 160 measured at the lower surface of the external insulating pattern 112 may be about 0.6 to about 0.9 times a width of the recesses 160 measured at the upper surface of the external insulating pattern 112. In this case, the width of the recesses 160 measured at the upper surface of the external insulating pattern 112 may be about 40 μm to about 100 μm. However, the inventive concept is not limited thereto, and the width of the recesses 160 may be constant in the second direction D2. A third distance R3 between the recesses 160 adjacent in the first direction D1 may be about 0.8 times to about 1.2 times the second distance R2 between the adjacent substrate pads 130 in the first direction D1. Both the holes 140 and the recesses 160 may be described herein as holes, with the holes 140 being examples of column-shaped holes, for example having a circular or equilateral polygonal shape from a plan view, and holes 160 being examples of trench-shaped holes, for example, having a horizontally elongated linear shape from a plan view.

Although not shown in FIG. 4, a protective layer may be formed on the upper surface of the substrate 100. The protective layer may be substantially the same or similar to the protective layer 200 (see FIG. 1) described in FIG. 1. The protective layer may entirely cover an upper surface of the external insulating pattern 112 and fill the recesses 160. The protective layer entirely covers the upper surface of the substrate 100 and may have an opening exposing at least a portion of each pad of the substrate pads 130. As the protective layer fills the recesses 160 and covers the upper surface of the substrate 100, the protective layer may have protrusions that protrude from the lower surface of the protective layer. The protective layer may include a gel-soft polymer such as a solder resist material. The protective layer may include an insulating material. For example, the insulating material may include one of epoxy resin, polyimide resin, BT resin, and Teflon resin.

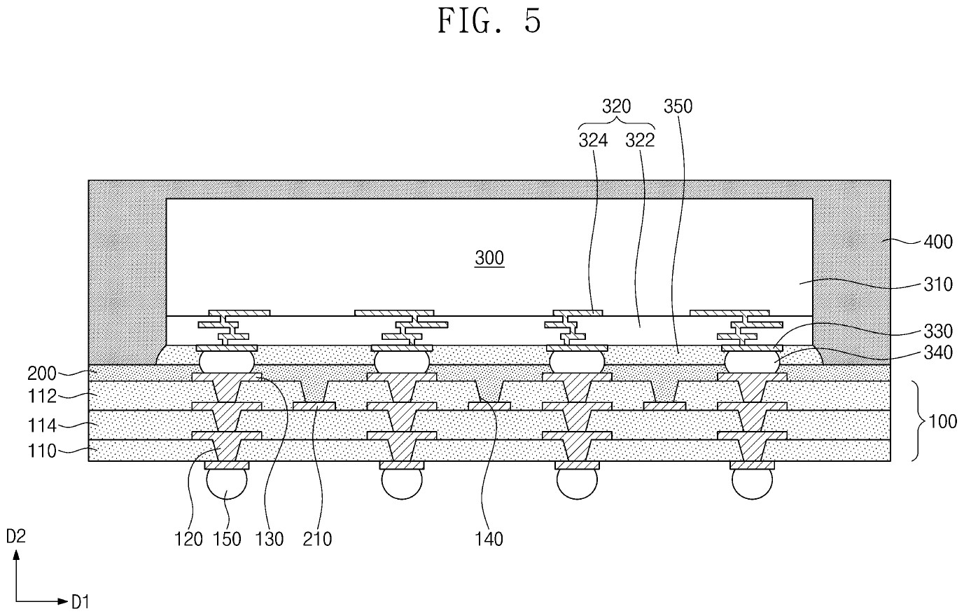

FIG. 5 is a cross-sectional view for illustrating a semiconductor package according to embodiments of the inventive concept. FIG. 5 shows that the number of substrate pads and penetration holes of the semiconductor package is small for convenience of explanation.

Referring to FIG. 5, the substrate 100 may further include protective patterns 210 disposed at a lower surface of the external insulating pattern 112. The protective patterns 210 may be formed on an upper surface of the internal insulating pattern 114. The protective patterns 210 may protrude from the upper surface of the internal insulating pattern 114 and may penetrate a portion of the external insulating pattern 112 to be formed in the external insulating pattern 112. The protective patterns 210 may extend horizontally on the upper surface of the internal insulating pattern 114. Each side surface of the protective patterns 210 may be covered by the external insulating pattern 112 disposed on the upper surface of the internal insulating pattern 114. The protective patterns 210 may be horizontally spaced apart from the first conductive pattern 120 disposed on the upper surface of the internal insulating pattern 114. The protective patterns 210 may not be electrically connected to the first conductive pattern 120 in the substrate 100. Therefore, the protective patterns 210 may be spaced apart from the first conductive pattern 120 and may be electrically floated in the substrate 100.

Each of the protective patterns 210 may be disposed between two of the adjacent substrate pads 130. Penetration holes 140 may be disposed on the upper surface of the protective patterns 210. The penetration holes 140 may vertically penetrate the external insulating pattern 112 so that the bottom of the penetration holes 140 terminate at the upper surfaces of the protective patterns 210. As the protective layer 200 fills the penetration holes 140, the protective patterns 210 and the protective layer 200 may be in contact with each other on the upper surface of the protective patterns 210. A width of each of the protective patterns 210 may be equal to or larger than a width of each of the penetration holes 140. For example, a maximum width of a top surface of each of the protective patterns 210 may be equal to or larger than a maximum width of a bottommost surface of each of the penetration holes 140. The protective patterns 210 may protrude beyond the side surfaces of the penetration holes 140. A maximum width of each of the protective patterns 210 may be smaller than a minimum distance between any two of the adjacent substrate pads 130. The protective patterns 210 may define positions where the penetration holes 140 are disposed and depths of the penetration holes 140. A depth of the penetration holes 140 may be equal to a distance from the upper surface of the external insulating pattern 112 to the upper surface of the protective patterns 210.

The protective patterns 210 may include a conductive material. For example, the conductive material may include copper (Cu) or aluminum (Al). When the protective patterns 210 include the conductive material, a material forming the protective patterns 210 and a material forming the first conductive pattern 120 may be the same.

FIG. 5 shows that the protective patterns 210 including a conductive material may be provided on the upper surface of the internal insulating pattern 114, and the material forming the protective patterns 210 is the same as the material forming the first conductive pattern 12, but the inventive concept is not limited thereto.

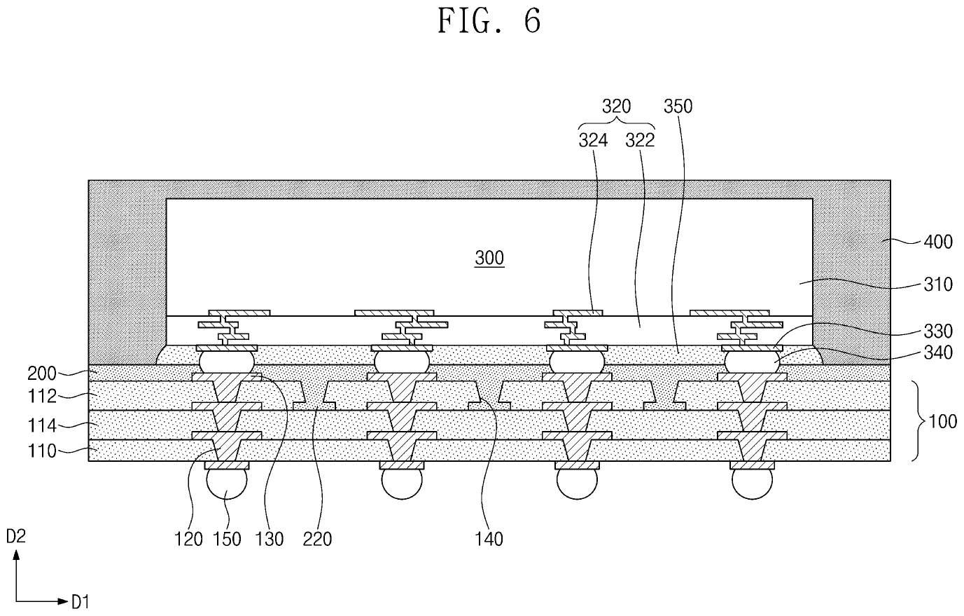

FIG. 6 is a cross-sectional view for illustrating a semiconductor package according to embodiments of the inventive concept. FIG. 6 shows that the number of substrate pads and penetration holes of the semiconductor package is small for convenience of explanation. Referring to FIG. 6, protective patterns 220 may be provided. The protective patterns 220 may correspond to the protective patterns 210 (see FIG. 5) described with reference to FIG. 5. The arrangement and shape of the protective patterns 220 may be substantially the same or similar to the protective patterns 210 described with reference to FIG. 5. For example, the protective patterns 220 may be disposed on the upper surface of the internal insulating pattern 114, and penetration holes 140 may be disposed on a top of the protective patterns 220. A width of each of the protective patterns 220 may be equal to or larger than a width of the penetration holes 140. The protective patterns 220 may protrude from the side surfaces of the penetration holes 140.

However, unlike FIG. 5, the protective patterns 220 may include a gel-soft polymer such as a solder resist material. The protective patterns 220 may include an insulating material. For example, the insulating material may include one of epoxy resin, polyimide resin, BT resin, and Teflon resin. The material forming the protective patterns 220 may be the same as the material forming the protective layer 200. The protective layer 200 may fill the penetration holes 140 and may connect with the upper portions of the protective patterns 220. The protective patterns 220 and the protective layer 200 may be formed integrally. The protective patterns 220 may have a continuous body with the protective layer 200, and an interface between the upper surfaces of the protective patterns 220 and the protective layer 200 may not be visually distinguished. For example, the protective patterns 220 may be portion of the protective layer 200 that fills an empty space formed in the lower portion of the penetration holes 140. However, the inventive concept is not limited thereto. The upper surface of the protective patterns 220 and the protective layer 200 may not have a continuous body, and the interface between the upper surface of the protective patterns 220 and the protective layer 200 may be visually distinguished.

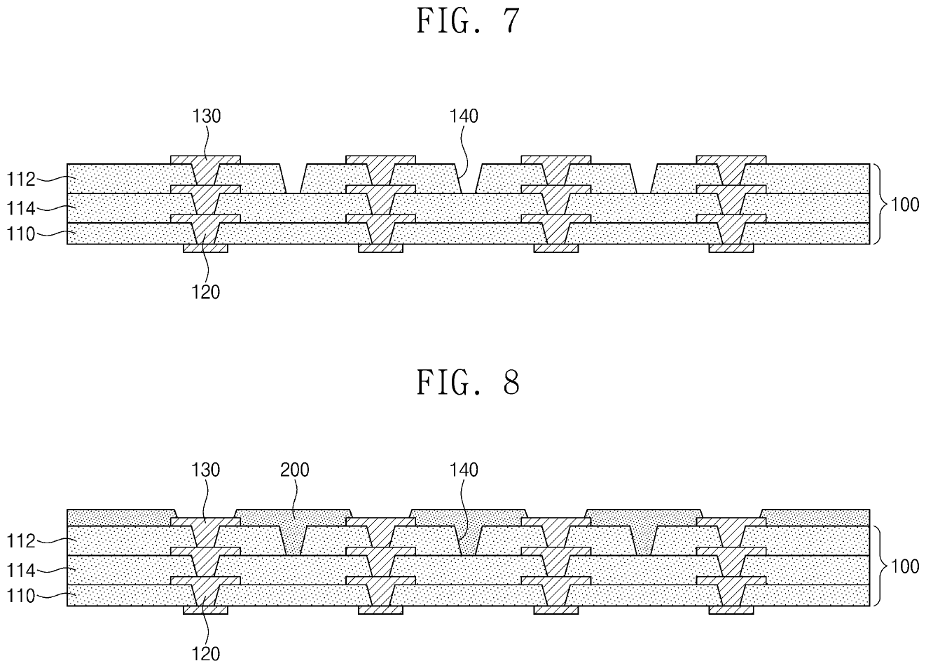

FIGS. 7 to 11 are cross-sectional views for illustrating a method of manufacturing a semiconductor package according to embodiments of the inventive concept. FIGS. 7 and 8 are cross-sectional views for illustrating a method of manufacturing a substrate according to embodiments of the inventive concept.

Referring to FIG. 7, the substrate 100 may be formed. For example, the first insulating patterns 110 and the first conductive pattern 120 may be formed to manufacture the substrate 100. Specifically, an insulating layer may be formed and may be patterned to form the first insulating pattern 110. A conductive layer may be formed on and in the insulating layer and may be patterned to form the first conductive pattern 120. In this case, a portion of the first conductive pattern 120 may be exposed on the first insulating pattern 110. As described above, one substrate wiring layer may be formed, and the substrate 100 having a plurality of substrate wiring layers may be formed by repeatedly performing the above process. In this case, the first insulating pattern 110 of the substrate wiring layer positioned at the uppermost end of the substrate 100 among the plurality of substrate wiring layers may be referred to as the external insulating pattern 112 and the first insulating pattern 110 of the substrate wiring layer disposed on the lower surface of the external insulating pattern 112 may be referred to as the internal insulating pattern 114.

The penetration holes 140 may be formed in the external insulating pattern 112. The penetration holes 140 may be formed through a laser process. A laser may be radiated onto the external insulating pattern 112 to pattern the external insulating pattern 112, and thus the penetration holes 140 may be formed. The penetration holes 140 may expose the upper surface of the internal insulating pattern 114 of the substrate 100. A depth of the penetration holes 140 may be formed to be the same as a height of the external insulating pattern 112. The depth of the penetration holes 140 may be variously changed depending on wavelength and type of the laser being irradiated.

As described above in connection with FIG. 7, the penetration holes 140 may be formed by a laser process, but the inventive concept is not limited thereto. The process for forming the penetration holes 140 may be variously changed depending on a material of the first insulating pattern 110. For example, when the material constituting the first insulating pattern 110 is photoimageable dielectric (PID), the penetration holes 140 may be formed through an exposure process. A first mask pattern may be formed on the upper surface of the external insulating pattern 112. The first mask pattern may have patterns that expose the upper surface of the external insulating pattern 112. For example, the first mask pattern may have first patterns disposed on the external insulating pattern 112, and the first patterns may define an region where the penetration holes 140 are formed. After the external insulating pattern 112 is etched to form the penetration holes 140, the first mask pattern may be removed.

Referring to FIG. 8, a protective layer 200 is formed on the upper surface of the substrate 100. The protective layer 200 may include a gel-soft polymer, such as a solder resist material. A material forming the protective layer 200 may be coated on the upper surface of the substrate 100 to cover the entire upper surface of the external insulating pattern 112. The protective layer 200 may fill the penetration holes 140. Thereafter, a second mask pattern may be formed on the upper surface of the protective layer 200. The second mask pattern may have patterns that expose the upper surface of the protective layer 200. For example, the second mask pattern may have second patterns located on the protective layer 200. The second patterns may have openings exposing the substrate pads 130. An region where connection terminals 340 are provided on the upper surface of the substrate pads 130 may be defined by the second patterns. After the protective layer 200 is etched to form a region where connection terminals 340 are provided, the second mask pattern may be removed.

As the protective layer 200 fills the penetration holes 140 and the surface area in contact between the protective layer 200 and the external insulating pattern 112 increases, adhesion between the protective layer 200 and the external insulating pattern 112 may be improved. Accordingly, a semiconductor package with improved structural stability may be provided. In this way, the substrate 100 described with reference to FIG. 1 may be manufactured.

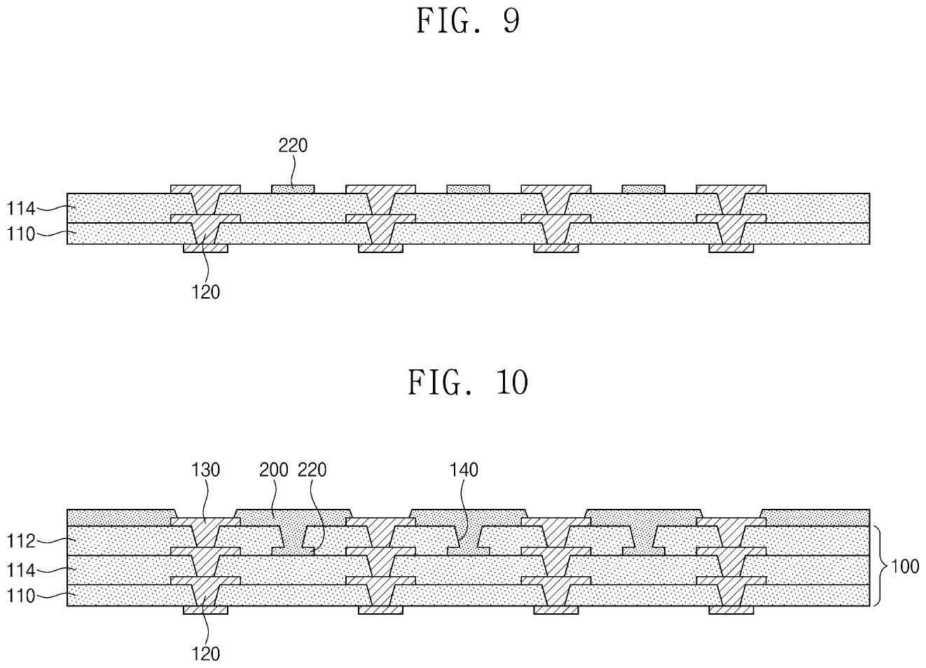

FIGS. 9 and 10 are cross-sectional views for illustrating a method of manufacturing a substrate according to embodiments of the inventive concept.

Referring to FIG. 9, a lower substrate region may be formed. For example, after forming an insulating layer, the insulating layer may be patterned to form the first insulating pattern 110. After forming a conductive layer on the insulating layer, the conductive layer may be patterned to form the first conductive pattern 120. In this case, a portion of the first conductive pattern 120 may be exposed on the first insulating pattern 110. As described above, one substrate wiring layer may be formed, and the lower substrate region having a plurality of substrate wiring layers may be formed by repeatedly performing the above process. The lower substrate region formed through the above processes may have one less substrate wiring layers than the substrate 100 (see FIG. 1) described with reference to FIGS. 1 to 8. The lower substrate region may correspond to the lower region of substrate 100 described with reference to FIG. 1, excluding the external insulating pattern 112 (see FIG. 1), the first conductive pattern 120 (see FIG. 1) disposed on the upper surface of the external insulating pattern 112, and the substrate pads 130 (see FIG. 1). For example, the internal insulating pattern 114, which is the first insulating pattern 110 disposed at the uppermost end of the lower region of the substrate, may correspond to the internal insulating pattern visible (see FIG. 1) of FIG. 1.

Protective patterns 220 may be formed on the upper surface of the internal insulating pattern 114. The protective patterns 220 may include a gel-soft polymer, such as a solder resist material. A material forming the protective patterns 220 may be coated on the upper surface of the internal insulating pattern 114 to cover the entire upper surface of the internal insulating pattern 114 and form an insulating layer. Thereafter, a third mask pattern may be formed on the upper surface of the insulating layer. The third mask pattern may have patterns that expose a portion of the upper surface of the insulating layer. For example, the third mask pattern may have third patterns located on the insulating layer. The third patterns may expose the remaining region of the insulating layer excluding the region where the protective patterns 220 are formed. A region where protective patterns 220 are provided may be defined by the third patterns. After the insulating layer is etched to form the protective patterns 220, the third mask pattern may be removed.

Referring to FIG. 10, the external insulating patterns 112 and substrate pads 130 may be formed. After forming the external insulating pattern 112 and forming a conductive layer on the external insulating pattern 112, the conductive layer may be patterned to form the first conductive pattern 120 and the substrate pads 130. In this case, the external insulating pattern 112 may cover the internal insulating pattern 114. The external insulating pattern 112 may cover the first conductive pattern 120 and the protective patterns 220 exposed on the upper surface of the internal insulating pattern 114. Thereafter, a laser may be radiated onto the external insulating pattern 112 to pattern the external insulating pattern 112 and form the penetration holes 140. The penetration holes 140 may expose a portion of the upper surface of the protective patterns 220. A depth of the penetration holes 140 may be variously changed depending on wavelength and type of the laser being radiated. A bottom of each of the penetration holes 140 may terminate at the upper surface of the corresponding protective patterns 220.

A protective layer 200 may be formed on the upper surface of the external insulating pattern 112. The protective layer 200 may be substantially the same or similar to the protective layer 200 (see FIG. 1) described in FIG. 1. The protective layer 200 may include a gel-soft polymer, such as a solder resist material. A material forming the protective layer 200 may be the same as a material forming the protective patterns 220. The material forming the protective layer 200 may be coated on the upper surface of the substrate 100 to cover the entire upper surface of the external insulating pattern 112. The material forming the protective layer 200 may fill the penetration holes 140. As the protective layer 200 fills the penetration holes 140, the protective layer 200 and the protective patterns 220 may be in contact with each other on the upper surfaces of the protective patterns 220. The protective patterns 220 may have a continuous body with the protective layer 200, and an interface between the upper surfaces of the protective patterns 220 and the protective layer 200 may not be visually distinguished. Therefore, the protective patterns 220 may be portion of the protective layer 200 that fills an empty space formed in the lower portion of the penetration holes 140.

Thereafter, a fourth mask pattern may be formed on the upper surface of the protective layer 200. The fourth mask pattern may be substantially the same as or similar to the second mask pattern described in FIG. 8. The fourth mask pattern may have patterns that expose the upper surface of the protective layer 200. After the protective layer 200 is etched to form a region on the substrate pads 130 where connection terminals 340 are provided, the fourth mask pattern may be removed. As described above, the substrate 100 described with reference to FIG. 6 may be formed.

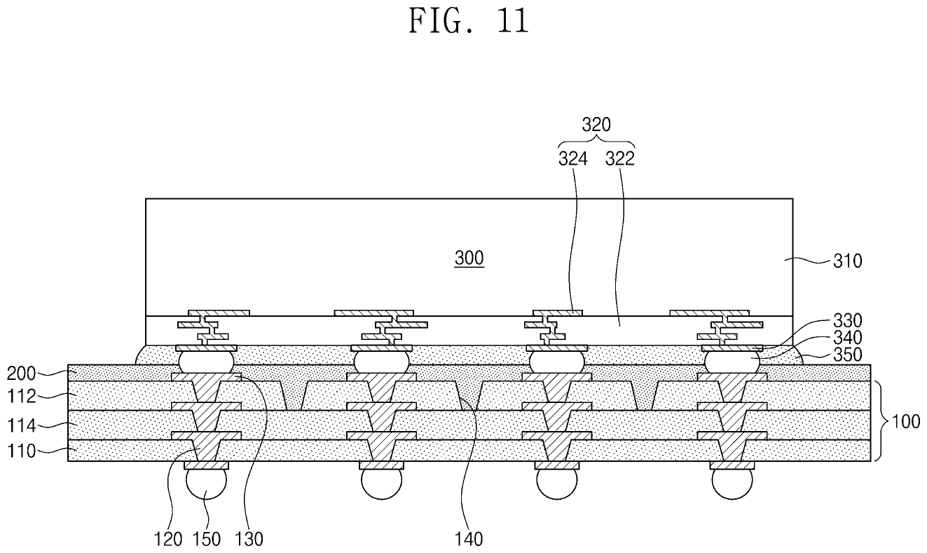

Referring to FIG. 11, a semiconductor chip 300 may be provided on the result of FIG. 8. In this case, the semiconductor chip 300 may be placed with an active surface facing the substrate 100. The semiconductor chip 300 may be mounted on the substrate 100 using connection terminals 340 disposed on the lower surface. The connection terminals 340 of the semiconductor chip 300 may be positioned on the substrate pads 130. Thereafter, the lower pads 330 of the semiconductor chip 300 and the substrate pads 130 of the substrate 100 may be electrically connected through a thermal compression process or a reflow process.

An underfill layer 350 may be provided between the upper surface of the substrate 100 and the semiconductor chip 300. The underfill layer 350 may fill a space between the substrate 100 and the semiconductor chip 300. For example, after applying an insulating material between the substrate 100 and the semiconductor chip 300, the underfill layer 350 may be formed by curing the insulating material. The underfill layer 350 may surround the connection terminals 340.

Referring again to FIG. 1, a molding layer 400 may be formed on the substrate 100. According to embodiments, the molding layer 400 may cover the semiconductor chip 300. Alternatively, an upper surface of the semiconductor chip 300 may be exposed to an upper surface of the molding layer 400.

External terminals 150 may be disposed on the lower surface of the substrate 100. The external terminals 150 may be provided on the lower surfaces of the lower pads of the substrate 100. For example, the external terminals 150, such as solder balls or solder bumps, may be attached to lower surfaces of the lower pads of the substrate. As described above, the semiconductor package of FIG. 1 may be manufactured.

In the semiconductor package according to embodiments of the inventive concept, the insulating layer may be connected to the inside surface (e.g., inner side surfaces or sidewalls) of the outermost layer of the substrate, and thus the extrusion phenomenon of the insulating layer may be reduced, thereby providing the semiconductor package with the improved structural stability.

In addition, in the semiconductor package according to embodiments of the inventive concept, the position of the connection terminal may be fixed by the insulating layer provided on the upper surface of the substrate, thereby reducing the short circuit defects in the connection terminal and improving the electrical stability.

While embodiments are described above, a person skilled in the art may understand that many modifications and variations may be made without departing from the spirit and scope of the invention as defined in the following claims. Accordingly, the example embodiments of the inventive concept should be considered in all respects as illustrative and not restrictive, with the spirit and scope of the invention being indicated by the appended claims.

1. A semiconductor package comprising:
a substrate,
wherein the substrate includes:
a first insulating pattern;
first conductive patterns extending horizontally on an upper surface of the first insulating pattern;
a second insulating pattern covering the first conductive patterns on the upper surface of the first insulating pattern;
substrate pads disposed on the second insulating pattern and being part of respective second conductive patterns that vertically penetrate the second insulating pattern and are connected to the first conductive patterns; and
an insulating layer covering the substrate pads on the second insulating pattern and exposing a portion of each substrate pad of the substrate pads,
wherein the second insulating pattern has penetration holes vertically penetrating the second insulating pattern,
wherein each of the penetration holes is disposed between two adjacent pads of the substrate pads, and
wherein the insulating layer fills the penetration holes.

2. The semiconductor package of claim 1, wherein the penetration holes vertically penetrate the second insulating pattern, and an upper surface of the first insulating pattern is exposed by the penetration holes.

3. The semiconductor package of claim 1, wherein the penetration holes have a recessed shape from an upper surface of the second insulating pattern toward an inside surface of the second insulating pattern, and
wherein a level of a bottom surface of the insulating layer in the penetration holes is higher than a level of a lower surface of the second insulating pattern.

4. The semiconductor package of claim 1, wherein the penetration holes vertically penetrate at least a portion of the first insulating pattern and the second insulating pattern, and
wherein a bottom of the penetration holes terminate at a level lower than a level of the uppermost surface of the first insulating pattern.

5. The semiconductor package of claim 1, wherein the penetration holes have a maximum width of about 40 μm to about 100 μm.

6. The semiconductor package of claim 1, wherein the substrate further includes protective patterns provided at a bottom of the penetration holes,
wherein the penetration holes penetrate vertically through the second insulating pattern, and
wherein an upper surface of the protective patterns is exposed by the penetration holes.

7. The semiconductor package of claim 1, wherein a distance between two adjacent penetration holes is about 0.8 to about 1.2 times a distance between two adjacent substrate pads.

8. The semiconductor package of claim 1, wherein a width of the penetration holes increases as a distance from the first insulating pattern increases.

9. The semiconductor package of claim 1, wherein the substrate pads are arranged in a plurality of rows extending in a first direction,
wherein each penetration hole is disposed between two adjacent rows of the plurality of rows of the substrate pads,
wherein each penetration hole is a recess having an elongated shape, and
wherein the recess extends in the first direction.

10. (canceled)

11. The semiconductor package of claim 1, further comprising:
a semiconductor chip disposed on an upper surface of the substrate;
a molding layer surrounding the semiconductor chip on the upper surface of the substrate;
an external terminal disposed on a lower surface of the substrate; and
a connection terminal provided on a lower surface of the semiconductor chip.

12. A semiconductor package comprising:
a substrate,
wherein the substrate includes:
a protective pattern;
a first conductive pattern horizontally spaced apart from the protective pattern;
a first insulating pattern covering the protective pattern and the first conductive pattern;
a penetration hole vertically penetrating the first insulating pattern;
a substrate pad disposed at an upper surface of the first conductive pattern; and
an insulating layer covering an upper surface of the first insulating pattern and surrounding a side surface of the substrate pad,
wherein the penetration hole is disposed on an upper surface of the protective pattern,
wherein the upper surface of the protective pattern is exposed by the penetration hole, and
wherein the insulating layer fills the penetration hole and covers the exposed upper surface of the protective pattern.

13. The semiconductor package of claim 12, wherein the first conductive pattern and the protective pattern are formed of the same material.

14. The semiconductor package of claim 12, wherein the substrate pad is one of a plurality of substrate pads and the penetration hole is one of a plurality of penetration holes, and
wherein the penetration holes and the substrate pads are arranged alternately with each other in a first direction.

15. The semiconductor package of claim 12, wherein the penetration hole has a depth of about 10 μm to about 35 μm.

16. The semiconductor package of claim 12, wherein a shape of the penetration hole from a plan view is a circular shape, and
wherein the penetration hole has a maximum width of about 40 μm to about 100 μm.

17. (canceled)

18. A semiconductor package comprising:
a substrate;
a semiconductor chip disposed on an upper surface of the substrate;
a molding layer surrounding the semiconductor chip on the upper surface of the substrate;
an external terminal disposed on a lower surface of the substrate; and
a connection terminal provided on a lower surface of the semiconductor chip,
wherein the substrate includes:
an internal insulating pattern;
a first conductive pattern extending horizontally on a upper surface of the internal insulating pattern;
an external insulating pattern covering the first conductive pattern on the upper surface of the internal insulating pattern;
a second conductive pattern disposed on an upper surface of the external insulating pattern and vertically penetrating the external insulating pattern and connected to the first conductive pattern;
a substrate pad disposed on the upper surface of the external insulating pattern and being part of the second conductive pattern; and
a protective layer covering the upper surface of the external insulating pattern and having an opening exposing the substrate pad,
wherein the connection terminal is connected to the substrate pad through the opening in the protective layer,
wherein the protective layer includes a protrusion protruding from a lower surface of the protective layer,
wherein the protrusion has a first depth and extends from the lower surface of the protective layer in a direction perpendicular to the upper surface of the external insulating pattern, and
wherein the protective layer surrounds at least a portion of a side surface of the connection terminal.

19. The semiconductor package of claim 18, wherein the substrate further includes a metal layer provided at a lower surface of the external insulating pattern,
wherein the protrusion vertically penetrates the external insulating pattern, and
wherein a lower surface of the protrusion is coplanar with an upper surface of the metal layer.

20. The semiconductor package of claim 18, wherein the first depth is about ⅓ to about 1 times the thickness of the external insulating pattern.

21. The semiconductor package of claim 18, wherein a width of the protrusion decreases from an upper surface of the protrusion toward a lower surface of the protrusion, and
wherein a width of the protrusion at the lower surface is about 0.6 times to about 0.9 times a width of the protrusion at the upper surface.

22. The semiconductor package of claim 18, wherein the substrate pad is one of a plurality of substrate pads, and
wherein the protrusion is disposed between two adjacent pads of the substrate pads.
